(19) United States
(12) Patent Application Publication
(10) Pub. No.: US 2026/0198167 A1
(43) Pub. Date: Jul. 9, 2026

(54) VANADIUM-BASED ELECTRODE FOR PEROVSKITE PHOTOELECTRIC DEVICE, AND PEROVSKITE PHOTOELECTRIC DEVICE PREPARED BY USING VANADIUM-BASED ELECTRODE

(71) Applicant: Guangdong Mellow Energy Co. Ltd., ZHUHAI (CN)

(72) Inventors: CUILING ZHANG, ZHUHAI (CN); YANYAN GAO, ZHUHAI (CN)

(21) Appl. No.: 19/442,947

(22) Filed: Jan. 7, 2026

Related U.S. Application Data
(63) Continuation of application No. PCT/CN2024/104227, filed on Jul. 8, 2024.

(30) Foreign Application Priority Data
Jul. 7, 2023 (CN) 202310829253.9

(51) Int. Cl. H10K 30/82; H10K 30/40; H10K 71/60

(52) U.S. Cl. CPC H10K 30/82; H10K 30/40; H10K 71/60

(57) ABSTRACT

Provided is a vanadium-based electrode for a perovskite-based optoelectronic device, and a perovskite-based optoelectronic device fabricated using the same. The vanadium-based electrode for the perovskite-based optoelectronic device is a vanadium electrode or a vanadium-pure metal/alloy composite electrode formed by magnetron sputtering on a back side of the perovskite-based optoelectronic device. The vanadium electrode or the vanadium-alloy electrode is suitable for optoelectronic devices with perovskite layers. In this application, a vanadium metal or a multilayer composite structure including vanadium, copper, etc. is fabricated on a perovskite solar cell to produce a vanadium-based electrode. The vanadium-based electrode can enhance the stability of the perovskite solar cell and reduce the cost of the perovskite solar cell, which creates great potential for large-scale production of perovskite solar cells. Compared with the prior art, this application offers advantages such as simplicity, practicality, and suitability for industrialization.

### TECHNICAL FIELD

The present application relates to the technical field of back electrodes for perovskite-based optoelectronic devices, and in particular relates to a vanadium-based electrode for a perovskite-based optoelectronic device, and a perovskite-based optoelectronic device fabricated using the same.

### BACKGROUND

Perovskite materials possess outstanding optoelectronic properties. Perovskite solar cells have highly promising application prospects. However, the stability of current perovskite-based devices has always been a concern. A critical factor affecting the stability of a perovskite solar cell is that a metal back electrode (such as a Cu or Ag electrode) in the perovskite solar cell can react with a perovskite layer to cause degradation, thereby compromising the structural stability. Accordingly, the present application provides a corrosion-resistant vanadium-based electrode. Compared to pure copper or silver electrodes, the vanadium-based electrode can mitigate the reaction between a perovskite layer and an electrode layer to enhance the stability of a perovskite solar cell.

### SUMMARY

To solve the above technical problems, the present application provides a vanadium-based electrode for a perovskite-based optoelectronic device, and a perovskite-based optoelectronic device fabricated using the same.

In a first aspect, the present application provides a vanadium-based electrode for a perovskite-based optoelectronic device, which is achieved through the following technical solutions:
The vanadium-based electrode for the perovskite-based optoelectronic device is a vanadium electrode formed on a back side of the perovskite-based optoelectronic device.

Preferably, a fabrication method of a vanadium metal electrode as an electrode material for the perovskite-based optoelectronic device is as follows: conducting film deposition using a magnetron sputtering device to produce the vanadium metal electrode, where magnetron sputtering parameters are as follows: a sputtering current for a vanadium target is 0.10 A to 0.20 A, a flow rate of an Ar gas is controlled at 10 sccm to 20 sccm, and a deposition time is 10 min to 60 min.

The vanadium-based electrode for the perovskite-based optoelectronic device is a vanadium-pure metal/alloy composite electrode.

Preferably, a pure metal in the vanadium-pure metal/alloy composite electrode is one selected from the group consisting of copper, aluminum, and silver; and an alloy in the vanadium-pure metal/alloy composite electrode includes at least two selected from the group consisting of copper, aluminum, and silver.

Preferably, a vanadium metal in the vanadium-pure metal/alloy composite electrode is first formed on a back side of the perovskite-based optoelectronic device, and a pure metal or an alloy in the vanadium-pure metal/alloy composite electrode is then formed on a surface of the vanadium metal.

The vanadium-based electrode for the perovskite-based optoelectronic device is a vanadium/M/vanadium electrode formed on a back side of the perovskite-based optoelectronic device, where M includes at least one selected from the group consisting of copper, aluminum, and silver.

Compared to pure copper or silver electrodes, the electrode material in the present application can mitigate the reaction between a perovskite layer and an electrode layer to enhance the stability of a perovskite solar cell. The vanadium-based electrode in the present application can be fabricated by a simple method with abundantly available raw materials. Compared with the prior art, the present application offers advantages such as simplicity, practicality, and suitability for industrialization.

In a second aspect, the present application provides a perovskite solar cell fabricated using the electrode material for the perovskite-based optoelectronic device, which is achieved through the following technical solutions:
A structure of the perovskite solar cell fabricated using the electrode material for the perovskite-based optoelectronic device includes a substrate, a transparent electrode layer, a first interfacial layer, a nanoparticle modification layer, a perovskite film layer, a second interfacial layer, a buffer layer, and the vanadium-based electrode for the perovskite-based optoelectronic device that are sequentially stacked.

With the above technical solution, the perovskite solar cell fabricated can be endowed with improved operational stability and quality stability, which strengthens the competitive advantage of the perovskite solar cell to allow a promising market prospect.

Preferably, the transparent electrode layer is indium tin oxide (ITO) or fluorine-doped tin oxide (FTO); the first interfacial layer includes at least one selected from the group consisting of poly[bis(4-phenyl)(2,4,6-trimethylphenyl)amine] (PTAA), NiO, poly(3-hexylthiophene) (P3HT), SnO₂, and TiO₂; the second interfacial layer includes at least one selected from the group consisting of [6,6]-phenyl-C61-butyric acid methyl ester (PCBM), C₆₀, SnO₂, copper phthalocyanine, and P3HT; and a back electrode layer is the electrode material for the perovskite-based optoelectronic device.

Preferably, the structure of the perovskite solar cell includes a glass substrate, a transparent ITO film layer, a PTAA film layer, a nano-alumina modification layer, the perovskite film layer, a C₆₀ electron transport layer, a SnO₂ buffer layer, and the vanadium-based electrode that are sequentially stacked.

Preferably, a fabrication method of the perovskite solar cell fabricated using the electrode material for the perovskite-based optoelectronic device includes the following steps:
S1, forming the transparent electrode layer on a glass substrate by vapor deposition;
S2, preparing the first interfacial layer and a nano-alumina modification layer on an upper surface of the transparent electrode layer by spin-coating, where the first interfacial layer serves as a hole transport layer;
S3, preparing the perovskite film layer on an upper surface of the hole transport layer by spin-coating;
S4, preparing the second interfacial layer on an upper surface of the perovskite film layer by spin-coating, where the second interfacial layer serves as an electron transport layer;
S5, preparing the buffer layer on an upper surface of the electron transport layer by spin-coating, where a function of the buffer layer is to optimize a contact between PCBM and an electrode; and

S6, fabricating the electrode material for the perovskite-based optoelectronic device on an upper surface of the buffer layer by magnetron sputtering to produce the perovskite solar cell.

The fabrication method of the perovskite solar cell in the present application is relatively simple, and is beneficial for mass production.

In summary, the present application has the following advantages:
1. In the present application, a vanadium metal or a multilayer composite structure including vanadium, copper, etc. is fabricated on a perovskite solar cell to produce a vanadium-based electrode. The vanadium-based electrode can enhance the stability of the perovskite solar cell and reduce the cost of the perovskite solar cell, which creates great potential for large-scale production of perovskite solar cells.
2. The vanadium-based electrode in the present application can be fabricated by a simple method with abundantly available raw materials. Compared with the prior art, the present application offers advantages such as simplicity, practicality, and suitability for industrialization.

### BRIEF DESCRIPTION OF THE DRAWINGS

FIG. 1 is a schematic diagram of an overall structure in Example 1 of the present application;

FIG. 2 is a schematic diagram of an overall structure in Example 2 of the present application;

FIG. 3 is a schematic diagram of an overall structure in Example 3 of the present application;

FIG. 4 is a scanning electron microscopy image illustrating a structure of a perovskite solar cell based on a vanadium-based electrode in Example 1 of the present application;

FIG. 5 shows corresponding relationships among a thickness, an electrical conductivity, and a power of a vanadium film directly fabricated on a glass substrate;

FIG. 6 shows states of vanadium, copper, and silver films after being soaked in a perovskite solution for 0 h, 75 h, and 200 h;

FIG. 7 shows conditions of vanadium, copper, and silver films directly fabricated on glass substrates after being placed in a perovskite solution for 200 h;

FIG. 8 is a comparison diagram of J-V curves of a perovskite solar cell prepared in Example 1 and a perovskite solar cell fabricated with a silver electrode;

FIG. 9 is a comparison diagram of efficiencies of the perovskite solar cell prepared in Example 1 and the perovskite solar cell fabricated with the silver electrode after undergoing heat aging at 85° C. in air;

FIG. 10 is a comparison diagram of J-V curves of a perovskite solar cell prepared in Example 1 and a perovskite solar cell fabricated with a silver electrode;

FIG. 11 is a comparison diagram of efficiencies of the perovskite solar cell prepared in Example 1 and the perovskite solar cell fabricated with the silver electrode after undergoing heat aging in air; and

FIG. 12 is a comparison diagram of appearances (front and back sides) of the perovskite solar cell prepared in Example 1 and the perovskite solar cell fabricated with the silver electrode after undergoing heat aging in air.

### DETAILED DESCRIPTION OF THE EMBODIMENTS

The present application is described in further detail below with reference to examples and comparative examples.

### EXAMPLES

Example 1: The vanadium-based electrode for the perovskite-based optoelectronic device disclosed in the present application is a vanadium electrode formed on a back side of the perovskite-based optoelectronic device. A fabrication method of a vanadium metal electrode as the electrode material for the perovskite-based optoelectronic device is as follows: Film deposition is conducted using a magnetron sputtering device to produce the vanadium metal electrode. Magnetron sputtering parameters are as follows: a sputtering current for a vanadium target is 0.10 A to 0.20 A, a flow rate of an Ar gas is controlled at 10 sccm to 20 sccm, and a deposition time is 10 min to 60 min.

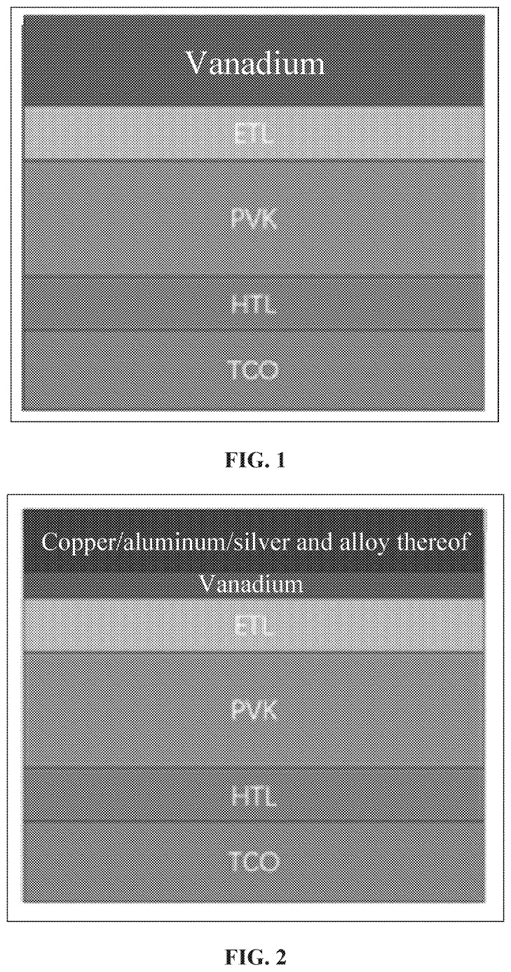

As shown in FIG. 1, a structure of a perovskite solar cell fabricated using the electrode material for the perovskite-based optoelectronic device includes a substrate, a transparent electrode layer, a first interfacial layer, a nanoparticle modification layer, a perovskite film layer, a second interfacial layer, a buffer layer, and a vanadium metal electrode that are sequentially stacked.

The transparent electrode layer is ITO or FTO.

The first interfacial layer includes at least one selected from the group consisting of PTAA, NiO, P3HT, SnO₂, and TiO₂.

The second interfacial layer includes at least one selected from the group consisting of PCBM, C₆₀, SnO₂, copper phthalocyanine, and P3HT.

A back electrode layer is a vanadium metal electrode.

A fabrication method of the perovskite solar cell with the vanadium metal electrode includes the following steps:
S1: The transparent electrode layer was formed on a glass substrate by vapor deposition.

S2: The first interfacial layer and the nanoparticle modification layer were prepared on an upper surface of the transparent electrode layer by spin-coating. The first interfacial layer served as a hole transport layer.

S3: The perovskite film layer was prepared on an upper surface of the hole transport layer by spin-coating.

S4: The second interfacial layer was prepared on an upper surface of the perovskite film layer by spin-coating. The second interfacial layer served as an electron transport layer.

S5: The buffer layer was prepared on an upper surface of the electron transport layer by spin-coating. A function of the buffer layer was to optimize a contact between PCBM and an electrode.

S6: A vanadium metal electrode with a thickness of 5 nm to 1,000 nm was fabricated on an upper surface of the buffer layer by magnetron sputtering to produce the perovskite solar cell. Magnetron sputtering parameters were as follows: a sputtering current for a vanadium target was 0.10 A to 0.20 A, a flow rate of an Ar gas was controlled at 10 sccm to 20 sccm, and a deposition time was 10 min to 60 min.

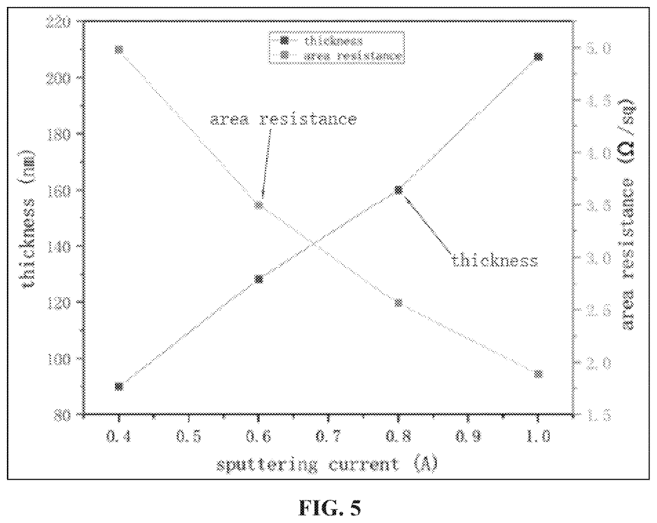

Specifically, as shown in FIG. 5, a perovskite solar cell fabricated using the electrode material for the perovskite-based optoelectronic device includes a glass substrate, a transparent ITO film layer, a PTAA film layer, a nano-alumina modification layer, the perovskite film layer, a C₆₀ electron transport layer, a SnO₂ buffer layer, and the vanadium-based electrode.

A fabrication method of the perovskite solar cell with the vanadium metal electrode includes the following steps:
S1: A transparent ITO film layer with a thickness of 200 nm was formed on the glass substrate by vapor deposition.

S2: A first interfacial layer (namely, a hole transport layer) was prepared on an upper surface of the transparent ITO film layer by spin-coating. Specifically, the first interfacial layer was a PTAA film layer with a thickness of 20 nm. A 10 nm-thick nano-alumina modification layer was then formed.

S3: A perovskite film layer with a thickness of 500 nm was prepared on an upper surface of the hole transport layer by spin-coating.

S4: A second interfacial layer was prepared on an upper surface of the perovskite film layer by spin-coating. The second interfacial layer was a C₆₀ electron transport layer with a thickness of 20 nm.

S5: A SnO₂ buffer layer with a thickness of 20 nm was prepared on an upper surface of the C₆₀ electron transport layer by spin-coating. A function of the SnO₂ buffer layer was to optimize a contact between C₆₀ and an electrode.

S6: A vanadium metal electrode with a thickness of 100±5 nm was fabricated on an upper surface of the SnO₂ buffer layer by magnetron sputtering to produce the perovskite solar cell. Magnetron sputtering parameters were as follows: a sputtering current for a vanadium target was 0.20 A, a flow rate of an Ar gas was controlled at 20 sccm, and a deposition time was controlled to achieve the thickness of the vanadium metal electrode.

Example 2 is different from Example 1 as follows: The vanadium-based electrode for the perovskite-based optoelectronic device is a vanadium-pure metal/alloy composite electrode. A pure metal in the vanadium-pure metal/alloy composite electrode is one selected from the group consisting of copper, aluminum, and silver. An alloy in the vanadium-pure metal/alloy composite electrode includes at least two selected from the group consisting of copper, aluminum, and silver. A vanadium metal in the vanadium-pure metal/alloy composite electrode is first formed on a back side of the perovskite-based optoelectronic device, and the pure metal or the alloy in the vanadium-pure metal/alloy composite electrode is then formed on a surface of the vanadium metal.

As shown in FIG. 2, a structure of a perovskite solar cell fabricated using the electrode material for the perovskite-based optoelectronic device includes a substrate, a transparent electrode layer, a first interfacial layer, a nanoparticle modification layer, a perovskite film layer, a second interfacial layer, a buffer layer, and the vanadium-pure metal/alloy composite electrode that are sequentially stacked.

Example 3 is different from Example 1 as follows: The vanadium-based electrode for the perovskite-based optoelectronic device is a vanadium/M/vanadium electrode formed on a back side of the perovskite-based optoelectronic device, where M includes at least one selected from the group consisting of copper, aluminum, and silver.

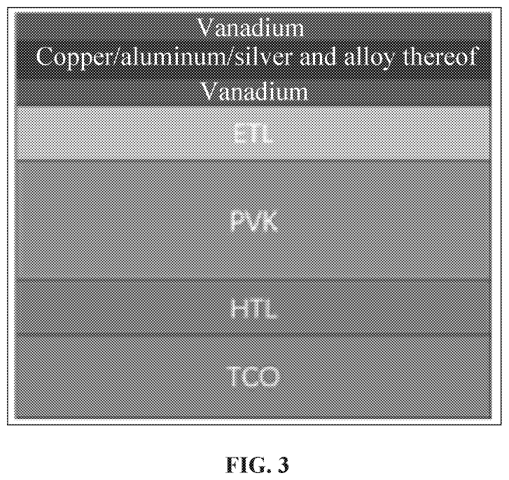

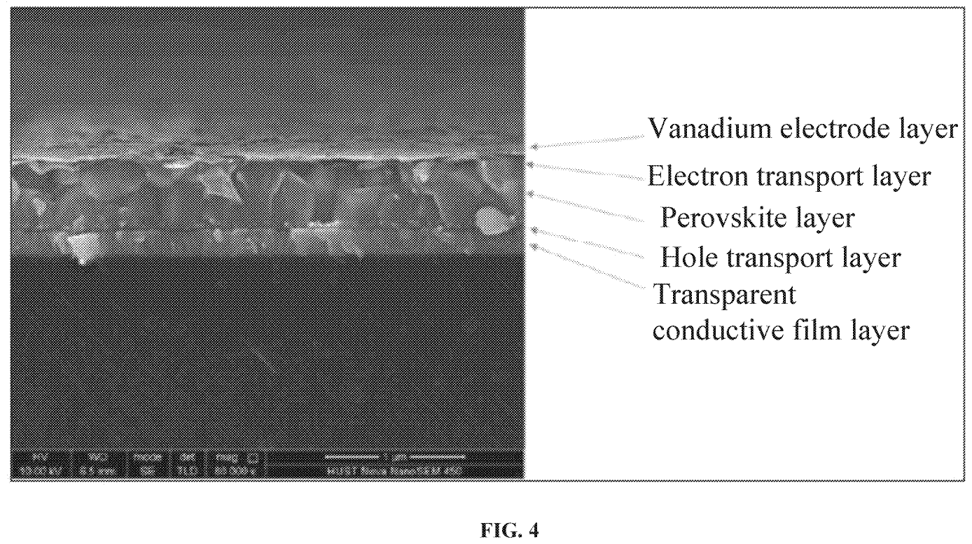

As shown in FIG. 3, a structure of a perovskite-based optoelectronic device fabricated using the electrode material for the perovskite-based optoelectronic device includes a substrate, a transparent electrode layer, a first interfacial layer, a nanoparticle modification layer, a perovskite film layer, a second interfacial layer, a buffer layer, and the vanadium/M/vanadium electrode that are sequentially stacked.

Comparative Example 1 is different from Example 1 as follows: An electrode for a perovskite-based optoelectronic device is a silver electrode formed on a back side of the perovskite-based optoelectronic device.

As shown in FIG. 5, the sheet resistance of a vanadium metal film is approximately directly proportional to a sputtering current, and a thickness of the vanadium metal film is roughly inversely proportional to sheet resistance.

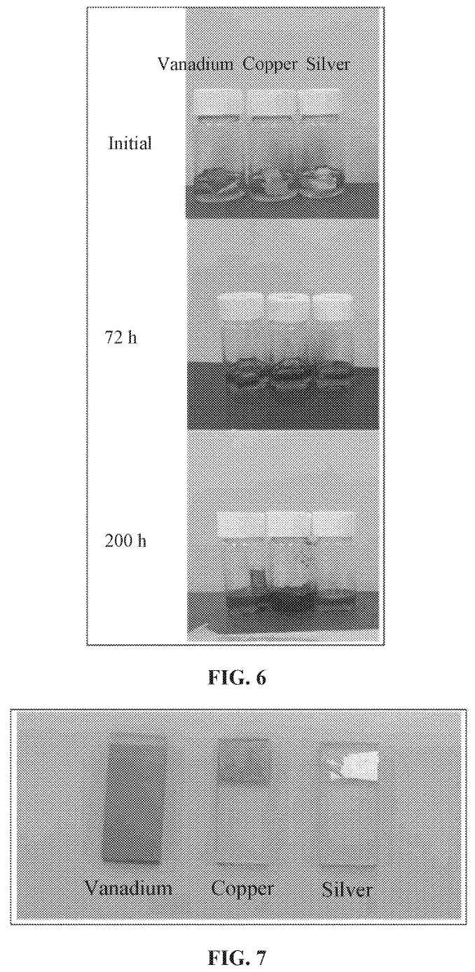

As shown in FIG. 6 to FIG. 7, after Ag, Cu, and V metal films are soaked in a perovskite solution for 100 min, regions of Ag and Cu films soaked in the perovskite solution have already reacted, but a V metal film undergoes no significant change and exhibits sheet resistance of about 1.29 Ω/sq that remains largely unchanged.

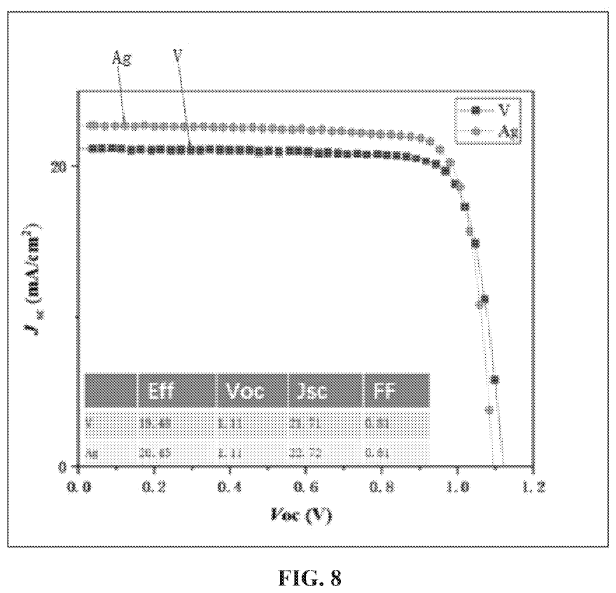

As shown in FIG. 8, a device with a V electrode is not much different from a device with a Ag electrode in terms of efficiency.

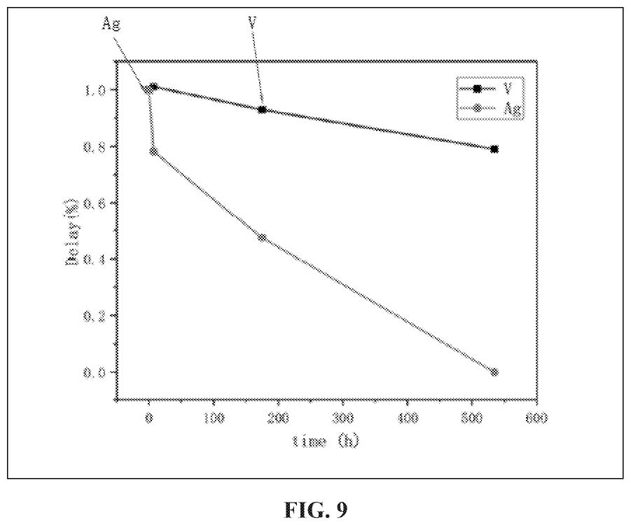

As shown in FIG. 9, after 500 h of heat aging at 85° C. in air, the device with the Ag electrode has lost its efficiency completely, while the device with the V electrode has still retained approximately 80% of its initial efficiency. The device with the V electrode exhibits significantly better stability than the device with the Ag electrode.

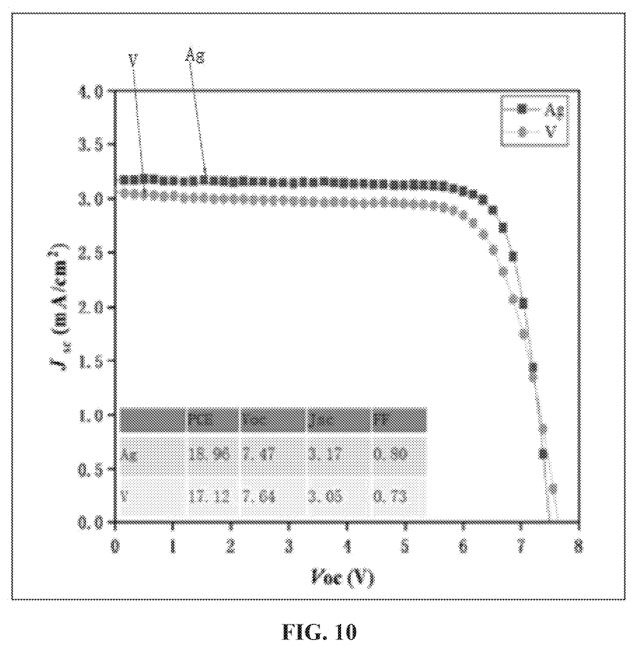

As shown in FIG. 10, a V electrode module exhibits an efficiency of 17%, and a Ag electrode module exhibits an efficiency close to 19%, indicating a relatively small difference in efficiency between the two.

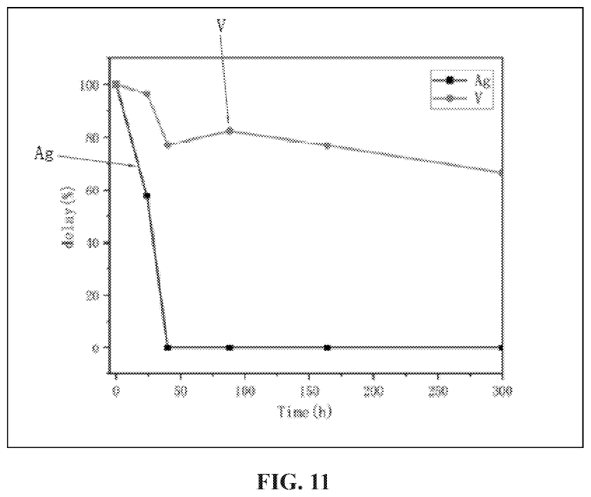

As shown in FIG. 11, the V electrode module has significantly better stability than the Ag electrode module.

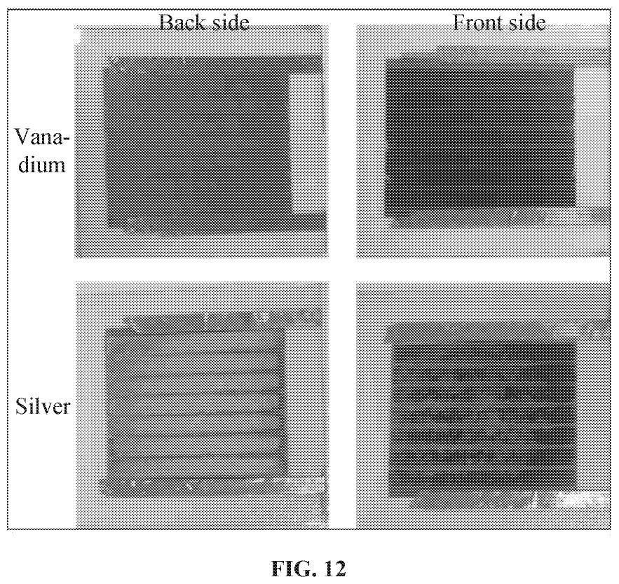

As shown in FIG. 12, the vanadium metal electrode provided in the present application exhibits excellent resistance to perovskite corrosion.

In summary, in the present application, a vanadium metal or a multilayer composite structure including vanadium, copper, etc. is fabricated on a perovskite solar cell to produce a vanadium-based electrode. The vanadium-based electrode can enhance the stability of the perovskite solar cell and reduce the cost of the perovskite solar cell, which creates great potential for large-scale production of perovskite solar cells. The vanadium-based electrode in the present application can be fabricated by a simple method with abundantly available raw materials. Compared with the prior art, the present application offers advantages such as simplicity, practicality, and suitability for industrialization.

These specific examples are only an explanation of the present application, but do not limit the present application. Those skilled in the art can make modifications without creative contribution to these examples as needed after reading this specification, but these modifications shall be protected under patent law within the scope of the claims of the present application.

What is claimed is:

1. A vanadium-based electrode for a perovskite-based optoelectronic device, wherein an electrode material for the perovskite-based optoelectronic device is a vanadium electrode formed on a back side of the perovskite-based optoelectronic device.

2. A vanadium-based electrode for a perovskite-based optoelectronic device, wherein an electrode material for the perovskite-based optoelectronic device is a vanadium-pure metal/alloy composite electrode.

3. The vanadium-based electrode for the perovskite-based optoelectronic device according to claim 2, wherein a pure metal in the vanadium-pure metal/alloy composite electrode is one selected from the group consisting of copper, aluminum, and silver; and an alloy in the vanadium-pure metal/alloy composite electrode comprises at least two selected from the group consisting of copper, aluminum, and silver.

4. The vanadium-based electrode for the perovskite-based optoelectronic device according to claim 2, wherein a vanadium metal in the vanadium-pure metal/alloy composite electrode is first formed on a back side of the perovskite-based optoelectronic device, and a pure metal or an alloy in the vanadium-pure metal/alloy composite electrode is then formed on a surface of the vanadium metal.

5. A vanadium-based electrode for a perovskite-based optoelectronic device, wherein an electrode material for the perovskite-based optoelectronic device is a vanadium/M/vanadium electrode formed on a back side of the perovskite-based optoelectronic device, wherein M comprises at least one selected from the group consisting of copper, aluminum, and silver.

6. The vanadium-based electrode for the perovskite-based optoelectronic device according to claim 1, wherein a fabrication method of a vanadium metal electrode as the electrode material for the perovskite-based optoelectronic device is as follows: conducting film deposition using a magnetron sputtering device to produce the vanadium metal electrode, wherein magnetron sputtering parameters are as follows: a sputtering current for a vanadium target is 0.10 A to 0.20 A, a flow rate of an Ar gas is controlled at 10 sccm to 20 sccm, and a deposition time is 10 min to 60 min.

7. A perovskite solar cell fabricated using the electrode material for the perovskite-based optoelectronic device according to claim 1, wherein a structure of the perovskite solar cell comprises a substrate, a transparent electrode layer, a first interfacial layer, a nanoparticle modification layer, a perovskite film layer, a second interfacial layer, a buffer layer, and the vanadium-based electrode for the perovskite-based optoelectronic device that are sequentially stacked.

8. The perovskite solar cell fabricated using the electrode material for the perovskite-based optoelectronic device according to claim 7, wherein the transparent electrode layer is indium tin oxide (ITO) or fluorine-doped tin oxide (FTO); the first interfacial layer comprises at least one selected from the group consisting of poly[bis(4-phenyl)(2,4,6-trimethylphenyl)amine] (PTAA), NiO, poly(3-hexylthiophene) (P3HT), SnO₂, and TiO₂; the second interfacial layer comprises at least one selected from the group consisting of [6,6]-phenyl-C61-butyric acid methyl ester (PCBM), C₆₀, SnO₂, copper phthalocyanine, and P3HT; and a back electrode layer is the electrode material for the perovskite-based optoelectronic device.

9. The perovskite solar cell fabricated using the electrode material for the perovskite-based optoelectronic device according to claim 7, wherein the structure of the perovskite solar cell comprises a glass substrate, a transparent ITO film layer, a PTAA film layer, a nano-alumina modification layer, the perovskite film layer, a C₆₀ electron transport layer, a SnO₂ buffer layer, and the vanadium-based electrode for the perovskite-based optoelectronic device that are sequentially stacked.

10. The perovskite solar cell fabricated using the electrode material for the perovskite-based optoelectronic device according to claim 7, wherein a fabrication method of the perovskite solar cell comprises following steps:
S1, forming the transparent electrode layer on a glass substrate by vapor deposition;
S2, preparing the first interfacial layer and a nano-alumina modification layer on an upper surface of the transparent electrode layer by spin-coating, wherein the first interfacial layer serves as a hole transport layer;
S3, preparing the perovskite film layer on an upper surface of the hole transport layer by spin-coating;
S4, preparing the second interfacial layer on an upper surface of the perovskite film layer by spin-coating, wherein the second interfacial layer serves as an electron transport layer;
S5, preparing the buffer layer on an upper surface of the electron transport layer by spin-coating, wherein a function of the buffer layer is to optimize a contact between PCBM and an electrode; and
S6, fabricating the electrode material for the perovskite-based optoelectronic device on an upper surface of the buffer layer by magnetron sputtering to produce the perovskite solar cell.
